(19) United States
(12) Patent Application Publication
(10) Pub. No.: US 2026/0059811 A1
(43) Pub. Date: Feb. 26, 2026

(54) TRANSISTOR AND MANUFACTURING METHOD THEREOF

(71) Applicant: Taiwan Semiconductor Manufacturing Company, Ltd., Hsinchu (TW)

(72) Inventors: Yi-Hong WANG, Hsinchu (TW); Yi-Chen LI, Hsinchu (TW); Hui-Hsuan KUNG, Hsinchu (TW); Chih-Hsiao CHEN, Hsinchu (TW); YI-LII HUANG, Hsinchu (TW)

(73) Assignee: Taiwan Semiconductor Manufacturing Company, Ltd., Hsinchu (TW)

(21) Appl. No.: 18/812,597

(22) Filed: Aug. 22, 2024

(51) Int. Cl. H01L 29/06; H01L 29/10; H01L 29/423; H01L 29/66; H01L 29/78

(52) U.S. Cl. CPC H10D 62/126; H10D 30/611; H10D 62/299; H10D 64/519; H10D 64/017

(57) ABSTRACT

A transistor and a manufacturing method are provided. The transistor includes at least one gate electrode, a channel, a gate dielectric layer, a source and a drain. The channel is curved. A doping concentration of a first portion of the channel is different from a doping concentration of a second portion of the channel. The gate dielectric layer is disposed between the gate electrode and the channel. The source is connected to the channel. The drain is connected to the channel.

### BACKGROUND

The disclosure relates in general to a transistor and a manufacturing method thereof, and more particularly to a high voltage transistor and a manufacturing method thereof.

The high voltage transistor needs special design to control the breakdown voltage and the resistance on the channel. Recently, Fin Field-Effect Transistor (FinFET) devices are becoming commonly used in integrated circuits. FinFET devices have a three-dimensional structure that comprises a semiconductor fin protruding from a substrate. A gate structure, configured to control the flow of charge carriers within a conductive channel of the FinFET device, wraps around the semiconductor fin. For example, in a tri-gate FinFET device, the gate structure wraps around three sides of the semiconductor fin, thereby forming conductive channels on three sides of the semiconductor fin.

How to make the FinFET devices being high-voltage transistors has become a research direction of researchers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a top view of a transistor according to one embodiment of the present disclosure.

FIG. 2A shows a cross-sectional view along a section line X-X′-1 in FIG. 1.

FIG. 2B shows a cross-sectional view along a section line X-X′-2 in FIG. 1.

FIG. 2C shows a cross-sectional view along a section line Y-Y′-1 in FIG. 1.

FIG. 2D shows a cross-sectional view along a section line Y-Y′-2 in FIG. 1.

FIGS. 3A to 3D show different designs for the channels of the transistors.

FIG. 4 shows a flowchart of a manufacturing method of the transistor according to one embodiment of the present disclosure.

FIG. 5 illustrates the manufacturing method of the transistor described in the FIG. 4.

FIG. 6 illustrates a manufacturing method of a transistor according to another embodiment of the present disclosure.

FIG. 7 illustrates a manufacturing method of a transistor according to another embodiment of the present disclosure.

FIG. 8 illustrates a manufacturing method of a transistor according to another embodiment of the present disclosure.

FIG. 9 illustrates a manufacturing method of a transistor according to another embodiment of the present disclosure.

FIG. 10 shows a top view of a transistor according to another embodiment of the present disclosure.

FIG. 11A shows a cross-sectional view along a section line X-X′-3 in FIG. 10.

FIG. 11B shows a cross-sectional view along a section line Y-Y′-3 in FIG. 10.

FIG. 11C shows a cross-sectional view along a section line Y-Y′-4 in FIG. 10.

FIG. 12 shows a top view of a transistor according to another embodiment of the present disclosure.

FIG. 13 shows a top view of a transistor according to another embodiment of the present disclosure.

FIG. 14 shows a top view of a transistor according to another embodiment of the present disclosure.

FIG. 15 shows a top view of a transistor according to another embodiment of the present disclosure.

FIG. 16A shows cross-sectional views along section lines Y-Y′-5, Y-Y′-6, Y-Y′-7 in FIG. 15.

FIG. 16B shows a cross-sectional view along a section line X-X′-5 in FIG. 15.

FIG. 16C shows a cross-sectional view along a section line X-X′-6 in FIG. 15.

FIG. 16D shows a cross-sectional view along a section line Y-Y′-8 in FIG. 15.

FIG. 16E shows a cross-sectional view along a section line Y-Y′-9 in FIG. 15.

FIG. 17 shows a top view of a transistor and a transistor according to another embodiment of the present disclosure.

FIG. 18 shows a circuit diagram of the transistor and the transistor in the FIG. 17.

FIG. 19 shows a top view of a transistor and a transistor according to another embodiment of the present disclosure.

FIG. 20 shows a circuit diagram of the transistor and the transistor in the FIG. 19.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “comprise,” “comprising,” “include,” “including,” “has,” “having,” etc. used in this specification are open-ended and mean “comprises but not limited.” The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

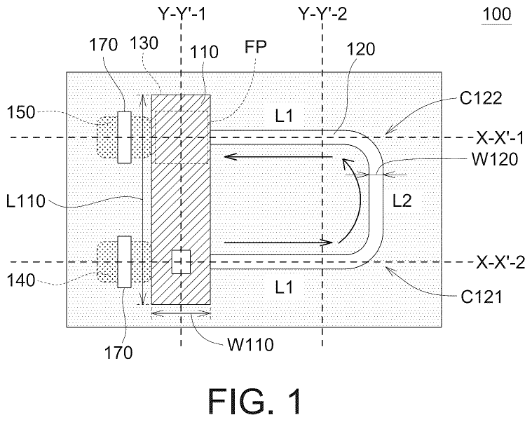

Please refer to FIG. 1, which shows a top view of a transistor 100 according to one embodiment of the present disclosure. The transistor 100 includes a gate electrode 110, a channel 120, a gate dielectric layer 130, a source 140 and a drain 150. The channel 120 is curved. The gate dielectric layer 130 is disposed between the gate electrode 110 and the channel 120. The source 140 is connected to the channel 120. The drain 150 is connected to the channel 120.

As shown in the FIG. 1, the channel 120 is U shaped. The channel 120 has two corners C121, C122. The length of the channel 120 is the sum of the two lengths L1 and the length L2. The width of the channel 120 is substantially identical. Most of the channel 120 is not covered by the gate electrode 110. The channel 120 is long, so the resistance of the channel 120 is large. High resistance of the channel 120 could allow the transistor 100 to sustain high voltage operation without breakdown.

In some embodiments, the width W110 of the gate electrode 110 is about 6 nm to 250 nm, and the length L110 of the gate electrode 110 is about 34 nm to 578 nm, but it is not used to limit the present disclosure. In one example, the width W110 of the gate electrode 110 may be 6 nm and the length L110 of the gate electrode 110 may be 240 nm. The length L110 of the gate electrode 110 could be 15 times of the width W110 of the gate electrode 110.

As shown in the FIG. 1, the length L1 is, for example, about 40 nm to 80 nm. The length L2 could be equal to the length L1. The width W120 of the channel 120 is, for example, 4 nm to 9 nm, which could be fin width. In one embodiment, the ratio of the length L1 to the length L2 may be 1.5 to 2.5, and the length L1 is substantially equal to the length L3. However, in some embodiments, the length L2 is larger than the length L1, and the length L1 is substantially equal to the length L3. The lengths L1, L2, and L3 depend on the LIT pattern layout.

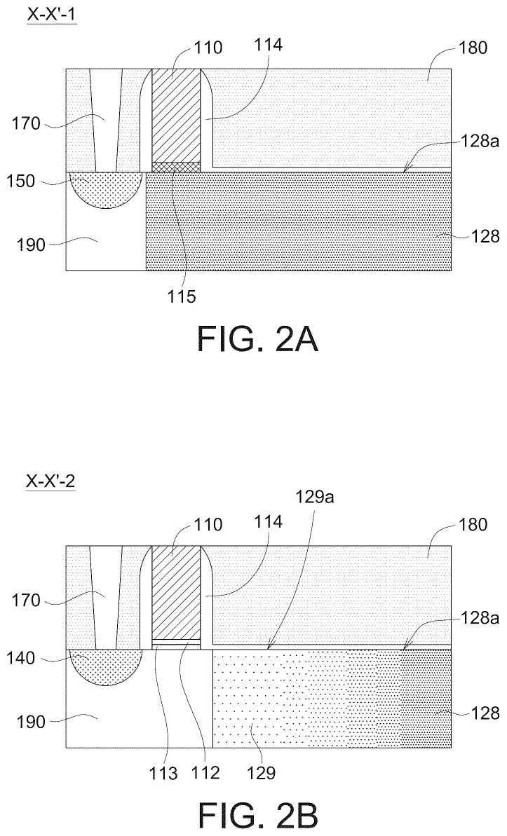

Please refer to FIG. 2A, which shows a cross-sectional view along a section line X-X′-1 in FIG. 1. At the section line X-X′-1, the gate electrode 110 is disposed above a N⁻ well 128. An oxide layer 115 is disposed between the gate electrode 110 and the N⁻ well 128. A spacer 114 covers the lateral walls of the gate electrode 110 and the top surface 128a of the N⁻ well 128. The drain 150 is disposed in a silicon layer 190. The silicon layer 190 may be slightly doped P-type dopants. A contact 170 is disposed on the drain 150. An interlayer dielectric (ILD) layer 180 covers the drain 150 and the N⁻ well 128.

Please refer to FIG. 2B, which shows a cross-sectional view along a section line X-X′-2 in FIG. 1. At the section line X-X′-2, the gate electrode 110 is disposed above the silicon layer 190. A high-k layer 112 and an interlayer 113 are disposed between the gate electrode 110 and the silicon layer 190. The spacer 114 covers the lateral walls of the gate electrode 110, a top surface 129a of the N⁺ well 129 and the top surface 128a of the N⁻ well 128. The doping concentration is gradually decreased from the N⁺ well 129 to the N⁻ well 128. The source 140 is disposed in the silicon layer 190. The contact 170 is disposed on the source 140. The ILD layer 180 covers the source 140, the N⁺ well 129 and the N⁻ well 128.

Please refer to FIG. 2C, which shows a cross-sectional view along a section line Y-Y′-1 in FIG. 1. At the section line Y-Y′-1, the gate electrode 110 is disposed above a STI structure 160 and coves a N⁻ fin 128f and a silicon fin 190f. The oxide layer 115 covers the N⁻ fin 128f. The high-k layer 112 and the interlayer 113 cover the silicon fin 190f.

Please refer to FIG. 2D, which shows a cross-sectional view along a section line Y-Y′-2 in FIG. 1. At the section line Y-Y′-2, the IDL 180 is disposed above the STI structure 160 and coves the N⁻ fin 128f and a N⁺ fin 129f. The oxide layer 115 covers the N⁻ fin 128f and the N⁺ fin 129f.

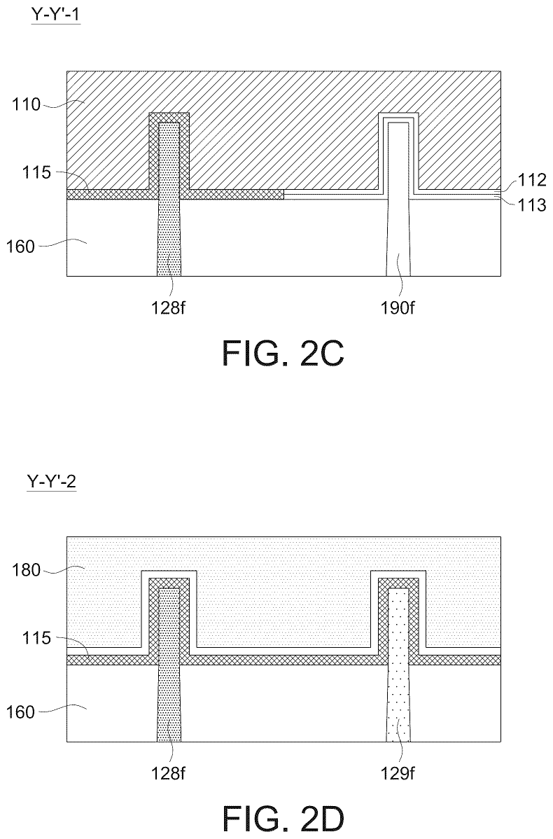

Please refer to FIGS. 3A to 3D, which show different designs for the channels 220, 320, 420, 520 of the transistors 100, 200, 300, 400, 500.

As shown in the FIG. 3A, the transistor 200 includes a gate electrode 210, a channel 220, a gate dielectric layer 230, a source 240 and a drain 250. The channel 220 is Ω shaped and substantially symmetrical. The source 240 and the drain 250 are disposed at two opposite sides of the gate electrode 210. The channel 220 is extended at the two opposite sides of the gate electrode 210. The channel 220 has four corners C221, C222, C223, C224. The length of the channel 220 is the sum of the two lengths L6, two lengths L4 and two lengths L5. In one embodiment, the ratio of the length L5 to the length L4 is 1 to 3, and the ratio of the length L4 to the length L6 is 1 to 3. The width W220 of the channel 220 is, for example, 4 nm to 9 nm, which could be fin width. The width W220 of the channel 220 is substantially identical. Most of the channel 220 is not covered by the gate electrode 210. The channel 220 is long, so the resistance of the channel 220 is large. High resistance of the channel 220 could allow the transistor 200 to sustain high voltage operation without breakdown.

As shown in the FIG. 3B, the transistor 300 includes a gate electrode 310, a channel 320, a gate dielectric layer 330, a source 340 and a drain 350. The channel 320 is M shaped and substantially symmetrical. The source 340 and the drain 350 are disposed at the same side of the gate electrode 310. The channel 320 is extended at another side of the gate electrode 310. The channel 320 has six corners C321, C322, C323, C324, C325, C326. The length of the channel 320 is the sum of the two lengths L1′, two lengths L2′, two lengths L3′ and one length L4′. In one embodiment, the ratio of the length L1′ to the length L2′, L3′ or L4′ is 1 to 3. The width W320 of the channel 320 is, for example, 4 nm to 9 nm, which could be fin width. The width W320 of the channel 320 is substantially identical. The width of the channel 320 is substantially identical. Most of the channel 320 is not covered by the gate electrode 310. The channel 320 is long, so the resistance of the channel 320 is large. High resistance of the channel 320 could allow the transistor 300 to sustain high voltage operation without breakdown.

As shown in the FIG. 3C, the transistor 400 includes a gate electrode 410, a channel 420, a gate dielectric layer 430, a source 440 and a drain 450. The channel 420 is ring shaped and substantially symmetrical. The source 440 and the drain 450 are disposed at the same side of the gate electrode 410. The channel 420 is extended at another side of the gate electrode 410. The channel 420 has six corners C421, C422, C423, C424, C425, C426. The length of the channel 420 is the sum of the two lengths L1′, two lengths L2′, two lengths L3″ and two lengths L4′. In one embodiment, the ratio of the length L1′ to the length L2′, L3″ or L4′ is 1 to 3. The width W420 of the channel 420 is, for example, 4 nm to 9 nm, which could be fin width. The width W420 of the channel 420 is substantially identical. Most of the channel 420 is not covered by the gate electrode 410. The channel 420 is long, so the resistance of the channel 420 is large. High resistance of the channel 420 could allow the transistor 400 to sustain high voltage operation without breakdown.

As shown in the FIG. 3D, the transistor 500 includes a gate electrode 510, a channel 520, a gate dielectric layer 530, two sources 540 and a drain 550. The channel 520 is finger shaped and substantially symmetrical. The sources 540 and the drain 550 are disposed at the same side of the gate electrode 510. The channel 520 is extended at another side of the gate electrode 510. The channel 520 has four corners C521, C522, C523, C524. The length of the channel 520 is the sum of the three lengths L1″ and two lengths L2″. In one embodiment, the ratio of the length L1″ to the length L2″ is 1 to 3. Each of the widths W521, W522, W523 of the channel 120 is, for example, 4 nm to 9 nm, which could be fin width. The width W521 or the width W522 of the channel 520 is less than the width W523 of the channel 520. Most of the channel 520 is not covered by the gate electrode 510. The channel 520 is long, so the resistance of the channel 520 is large. High resistance of the channel 520 could allow the transistor 500 to sustain high voltage operation without breakdown.

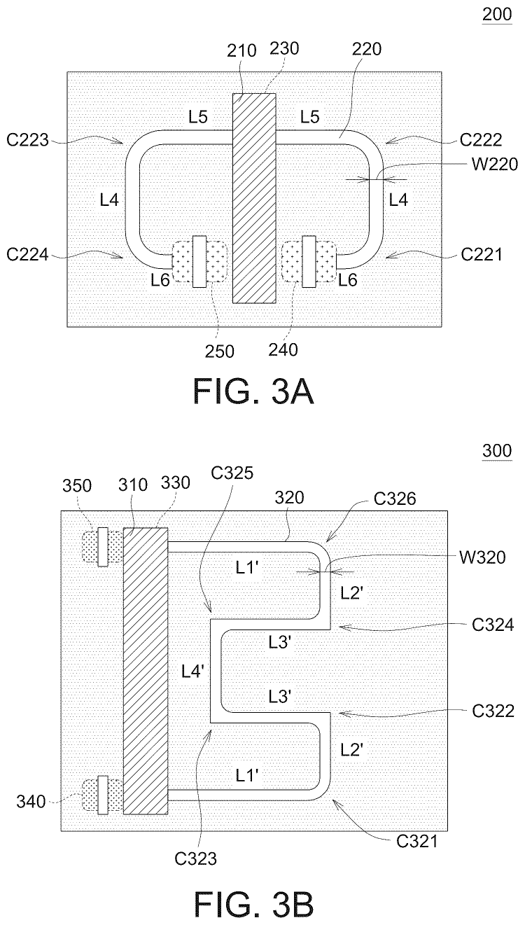

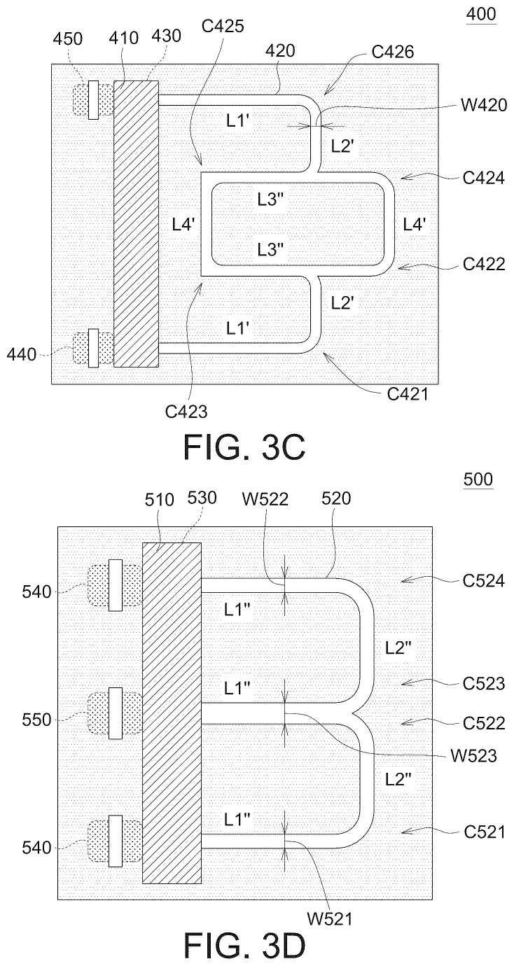

Please refer to FIGS. 4 and 5. FIG. 4 shows a flowchart of a manufacturing method of the transistor 100 according to one embodiment of the present disclosure. FIG. 5 illustrates the manufacturing method of the transistor 100 described in the FIG. 4. The manufacturing method includes, for example, steps S110 to S180. In the step S110, as shown in the drawing (a) of the FIG. 5, a ground pattern GP1 is formed on an oxide layer OX1 and a silicon layer SL1. The oxide layer OX1 is formed on the silicon layer SL1. The ground pattern GP1 is, for example, rectangular.

Then, in the step S120, as shown in the drawing (b) of the FIG. 5, a spacer SP1 is formed around the ground pattern GP1. The width of the spacer SP1 is, for example, the width of the channel 120 (shown in the drawing (g) of the FIG. 5).

Next, in the step S130, as shown in the drawing (c) of the FIG. 5, the ground pattern GP1 is removed.

Afterwards, in the step S140, as shown in the drawing (d) of the FIG. 5, a pattern of the spacer SP1 is transferred to the silicon layer SL1 to form a silicon ring SR1. In this step, the oxide layer OX1 and the silicon layer SL1 are etched by using the spacer SP1 as a mask.

Next, in the step S150, as shown in the drawing (e) of the FIG. 5, part of the silicon ring SR1 is cut. In this step, three sides of the silicon ring SR1 is covered by a photoresist layer and one side of the silicon ring SR1 which is not covered by the photoresist layer is removed by etching process. After removing, the silicon ring SR1 becomes U shaped.

Then, in the S160, as shown in the drawing (f) of the FIG. 5, a shallow trench isolation ST11 is formed, the shallow trench isolation ST11 is recessed to form a fin FN1 and then a dummy gate DG1 is formed.

Afterwards, in the S170, as shown in the drawing (g) of the FIG. 5, the fin FN1 is doped to form the channel 120, and then the source 140 and the drain 150 are formed. A dielectric layer ILD1 is formed for interlayer isolation. The source 140 and the drain 150 are formed at the side opposite to the channel 120.

Next, in the S180, as shown in the drawing (h) of the FIG. 5, the dummy gate DG1 is replaced by the gate electrode 110.

According to the disclosure in the FIGS. 4 and 5, the transistor 100 having the U shaped channel 120 is formed. The channel 120 is long, so the resistance of the channel 120 is large. High resistance of the channel 120 could allow the transistor 100 to sustain high voltage operation without breakdown.

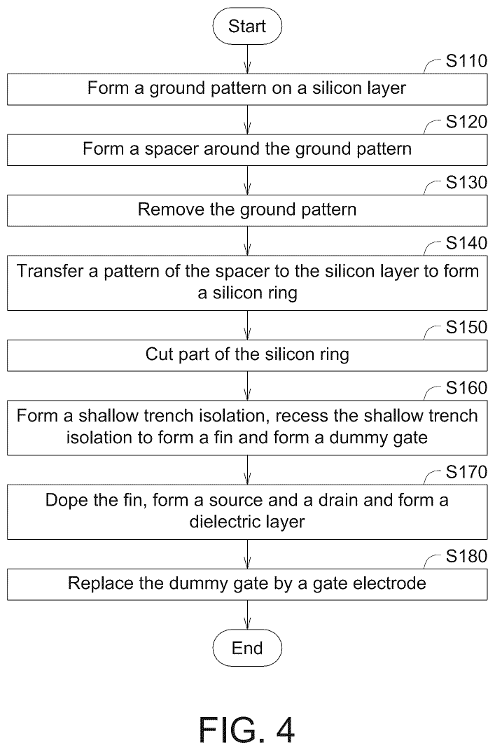

Please refer to FIG. 6, which illustrates a manufacturing method of the transistor 200 according to another embodiment of the present disclosure. In the step S110, as shown in the drawing (a) of the FIG. 6, a ground pattern GP2 is formed on an oxide layer OX2 and a silicon layer SL2. The oxide layer OX2 is formed on the silicon layer SL2. The ground pattern GP2 is, for example, rectangular.

Then, in the step S120, as shown in the drawing (b) of the FIG. 6, a spacer SP2 is formed around the ground pattern GP2. The width of the spacer SP2 is, for example, the width of the channel 220 (shown in the drawing (g) of the FIG. 6).

Next, in the step S130, as shown in the drawing (c) of the FIG. 6, the ground pattern GP2 is removed. As shown in the sectional view along a Y-Y′ cut line in the drawing (c) of the FIG. 6, the spacer SP2 is remained on an oxide layer OX2.

Afterwards, in the step S140, as shown in the drawing (d) of the FIG. 6, a pattern of the spacer SP2 is transferred to the silicon layer SL2 to form a silicon ring SR2. In this step, the oxide OX2 and the silicon layer SL2 are etched by using the spacer SP2 as a mask.

Next, in the step S150, as shown in the drawing (e) of the FIG. 6, part of the silicon ring SR2 is cut. In this step, portion of one long side of the silicon ring SR2 is covered by a photoresist layer and other portion of the silicon ring SR2 which is not covered by the photoresist layer is removed by etching process. After removing, the silicon ring SR2 becomes 2 shaped.

Then, in the S160, as shown in the drawing (f) of the FIG. 6, a shallow trench isolation STI2 is formed, the shallow trench isolation STI2 is recessed to form a fin FN2 and then a dummy gate DG2 is formed.

Afterwards, in the S170, as shown in the drawing (g) of the FIG. 6, the fin FN2 is doped to form the channel 220, and then the source 240 and the drain 250 are formed. A dielectric layer ILD2 is formed for interlayer isolation. The source 240 and the drain 250 are formed at the two opposite sides of the dummy gate DG2.

Next, in the S180, as shown in the drawing (h) of the FIG. 6, the dummy gate DG2 is replaced by the gate electrode 210. In this step, the gate dielectric layer 230 and a field plate FP2 are formed between the gate electrode 210 and the channel 220.

According to the disclosure in the FIGS. 4 and 6, the transistor 200 having the Ω shaped channel 220 is formed. The channel 220 is long, so the resistance of the channel 220 is large. High resistance of the channel 220 could allow the transistor 200 to sustain high voltage operation without breakdown.

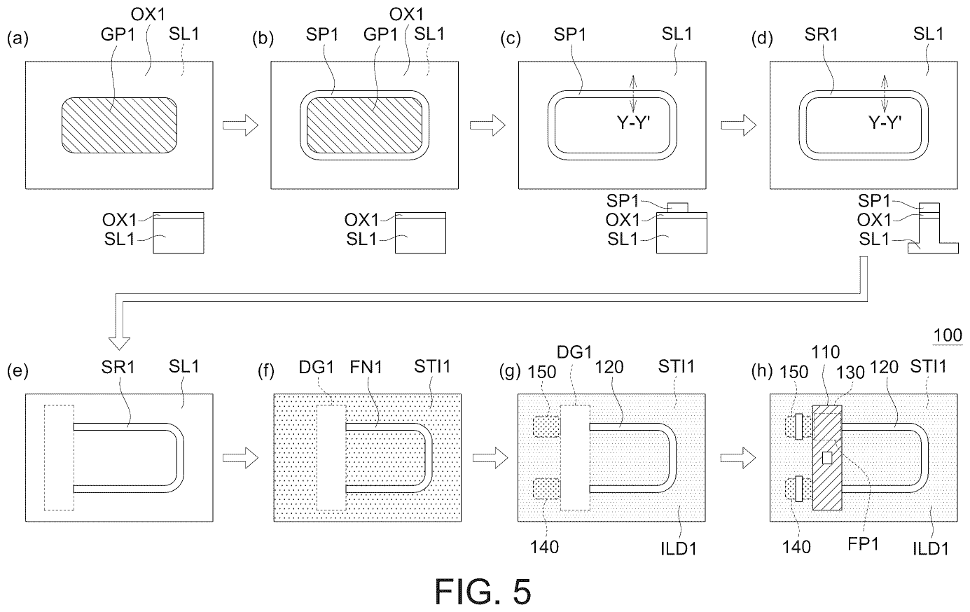

Please refer to FIG. 7, which illustrates a manufacturing method of the transistor 300 according to another embodiment of the present disclosure. In the step S110, as shown in the drawing (a) of the FIG. 7, three ground patterns GP31, GP32, GP33 are formed on an oxide layer OX3 and a silicon layer SL3. The oxide layer OX3 is formed on the silicon layer SL3. Each of the ground patterns GP31, GP32, GP33 is, for example, rectangular. In one embodiment, the width Wgp32 of the ground pattern GP32 is wider than the width Wgp31 of the ground pattern GP31, the width Wgp32 of the ground pattern GP32 is less than the width Wgp33 of the ground pattern GP33, and the width Wgp31 of the ground pattern GP31 is substantially identical to the width Wgp33 of the ground pattern GP33. In another embodiment the length Lgp32 of the ground pattern GP32 is designable and could be different from the length Lgp31 of the ground pattern GP31 or the length Lgp33 of the ground pattern GP33.

Then, in the step S120, as shown in the drawing (b) of the FIG. 7, a spacer SP3 is formed around the ground patterns GP31, GP32, GP33. The width of the spacer SP3 is, for example, the width of the channel 320 (as shown in the drawing (f) of the FIG. 7).

Next, in the step S130, as shown in the drawing (c) of the FIG. 7, the ground patterns GP31, GP32, GP33 are removed.

Afterwards, in the step S140, as shown in the drawing (d) of the FIG. 7, a pattern of the spacer SP3 is transferred to the silicon layer SL3 to form three silicon rings SR31, SR32, SR33 which are overlapped. In this step, the silicon layer SL3 is etched by using the spacer SP3 as a mask.

Next, in the step S150, as shown in the drawing (d) of the FIG. 7, part of the silicon rings SR31, SR32, SR33 are cut. In this step, portion of the silicon ring SR31, portion of the silicon ring SR32 and portion of the silicon ring SR33 are covered by a photoresist layer and other portions of the silicon rings SR31, SR32, SR33 which are not covered by the photoresist layer are removed by etching process. After removing, the silicon rings SR31, SR32, SR33 become M shaped.

Then, in the S160, as shown in the drawing (e) of the FIG. 7, a shallow trench isolation STI3 is formed, the shallow trench isolation STI3 is recessed to form a fin FN3 and a dummy gate DG3 is formed.

Afterwards, in the S170, as shown in the drawing (e) of the FIG. 7, the fin FN3 is doped to form the channel 320 (as shown in the drawing (f) of the FIG. 7), and then the source 340 and the drain 350 are formed. A dielectric layer ILD3 is formed for interlayer isolation. The source 340 and the drain 350 are formed at the same side of the dummy gate DG3.

Next, in the S180, as shown in the drawing (f) of the FIG. 7, the dummy gate DG3 is replaced by the gate electrode 310. In this step, the gate dielectric layer 330 and a field plate FP3 are formed between the gate electrode 310 and the channel 320.

According to the disclosure in the FIGS. 4 and 7, the transistor 300 having the M shaped channel 320 is formed. The channel 320 is long, so the resistance of the channel 320 is large. High resistance of the channel 320 could allow the transistor 300 to sustain high voltage operation without breakdown.

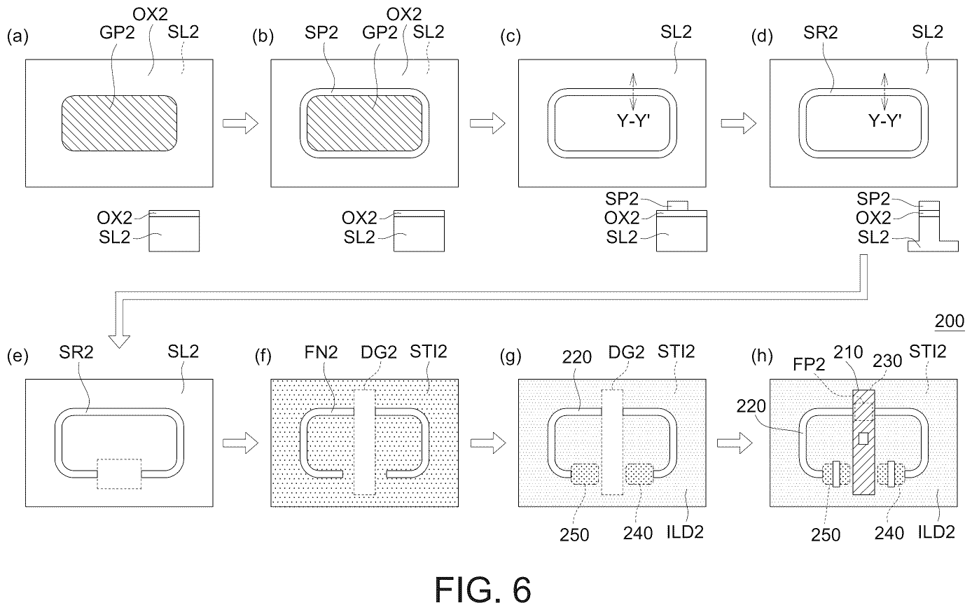

Please refer to FIG. 8, which illustrates a manufacturing method of the transistor 400 according to another embodiment of the present disclosure. In the step S110, as shown in the drawing (a) of the FIG. 8, three ground patterns GP41, GP42, GP43 are formed on an oxide layer OX4 and a silicon layer SL4. The oxide layer OX4 is formed on the silicon layer SL4. Each of the ground patterns GP41, GP42, GP43 is, for example, rectangular. In one embodiment, the width Wgp42 of the ground pattern GP42 is wider than the width Wgp41 of the ground pattern GP41, the width Wgp42 of the ground pattern GP42 is wider than the width Wgp43 of the ground pattern GP43, and the width Wgp41 of the ground pattern GP41 is substantially identical to the width Wgp43 of the ground pattern GP43. In another embodiment the length Lgp42 of the ground pattern GP42 is designable and could be different from the length Lgp41 of the ground pattern GP41 or the length Lgp43 of the ground pattern GP43.

Then, in the step S120, as shown in the drawing (b) of the FIG. 8, a spacer SP4 is formed around the ground patterns GP41, GP42, GP43. The width of the spacer SP4 is, for example, the width of the channel 420 (shown in the drawing (f) of the FIG. 8).

Next, in the step S130, as shown in the drawing (c) of the FIG. 8, the ground patterns GP41, GP42, GP43 are removed.

Afterwards, in the step S140, as shown in the drawing (d) of the FIG. 8, a pattern of the spacer SP4 is transferred to the silicon layer SL4 to form three silicon rings SR41, SR42, SR43 which are overlapped. In this step, the silicon layer SL4 is etched by using the spacer SP4 as a mask.

Next, in the step S150, as shown in the drawing (d) of the FIG. 8, part of the silicon rings SR41, SR43 are cut. In this step, portion of the silicon ring SR41 and portion of the silicon ring SR43 are covered by a photoresist layer and other portions of the silicon rings SR41, SR43 and the silicon ring SR43 which are not covered by the photoresist layer are removed by etching process. After removing, the silicon rings SR41, SR42, SR43 become ring shaped.

Then, in the S160, as shown in the drawing (e) of the FIG. 8, a shallow trench isolation STI4 is formed, the shallow trench isolation STI4 is recessed to form a fin FN4 and then a dummy gate DG4 is formed on the fin FN4 and the shallow trench isolation STI4.

Afterwards, in the S170, as shown in the drawing (e) of the FIG. 8, the fin FN4 is doped to form the channel 420 (shown in the drawing (f) of the FIG. 8), the source 440 and then the drain 450 are formed. A dielectric layer ILD4 is formed for interlayer isolation. The source 440 and the drain 450 are formed at the same side of the dummy gate DG4.

Next, in the S180, as shown in the drawing (f) of the FIG. 8, the dummy gate DG4 is replaced by the gate electrode 410. In this step, the gate dielectric layer 430 and a field plate FP4 are formed between the gate electrode 410 and the channel 420.

According to the disclosure in the FIGS. 4 and 8, the transistor 400 having the ring shaped channel 420 is formed. The channel 420 is long, so the resistance of the channel 420 is large. High resistance of the channel 420 could allow the transistor 400 to sustain high voltage operation without breakdown.

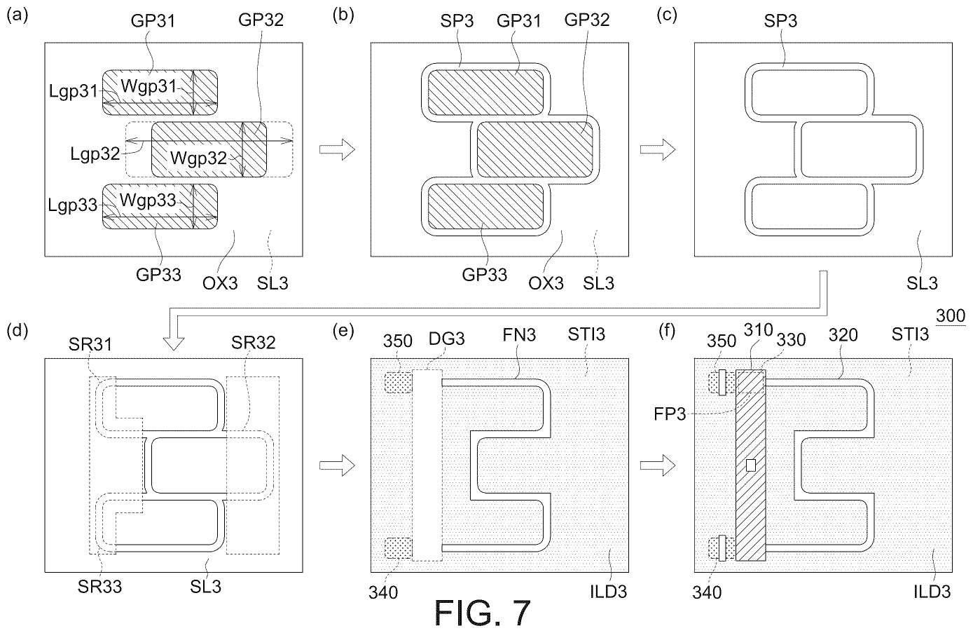

Please refer to FIG. 9, which illustrates a manufacturing method of the transistor 500 according to another embodiment of the present disclosure. In the step S110, as shown in the drawing (a) of the FIG. 9, two ground patterns GP51, GP52 are formed on an oxide layer OX5 and a silicon layer SL5. The oxide layer OX5 is formed on the silicon layer SL5. Each of the ground patterns GP51, GP52 is, for example, rectangular. In one embodiment, the width Wgp52 of the ground pattern GP52 is substantially identical to the width Wgp51 of the ground pattern GP51. The length Lgp52 of the ground pattern GP52 is substantially identical to the length Lgp51 of the ground pattern GP51.

Then, in the step S120, as shown in the drawing (b) of the FIG. 9, a spacer SP5 is formed around the ground patterns GP51, GP52. The width of the spacer SP5 is, for example, the width of the channel 520 (shown in the drawing (g) of the FIG. 9).

Next, in the step S130, as shown in the drawing (c) of the FIG. 9, the ground patterns GP51, GP52 are removed.

Afterwards, in the step S140, as shown in the drawing (d) of the FIG. 9, a pattern of the spacer SP5 is transferred to the silicon layer SL5 to form two silicon rings SR51, SR52 which are overlapped. In this step, the silicon layer SL5 is etched by using the spacer SP5 as a mask. The width Wsr512 of the overlapping of the silicon rings SR51, SR52 is larger than the width Wsr51 of the silicon ring SR51 or the width Wsr52 of the silicon ring SR52.

Next, in the step S150, as shown in the drawing (e) of the FIG. 9, part of the silicon rings SR51, SR52 are cut. In this step, portion of the silicon ring SR51 and portion of the silicon ring SR52 are covered by a photoresist layer and other portions of the silicon rings SR51, SR52 which are not covered by the photoresist layer are removed by etching process. After removing, the silicon rings SR51, SR52 become finger shaped.

Then, in the S160, as shown in the drawing (f) of the FIG. 9, a shallow trench isolation STI5 is formed, the shallow trench isolation STI5 is recessed to form a fin FN5 and then a dummy gate DG5 is formed.

Afterwards, in the S170, as shown in the drawing (g) of the FIG. 9, the fin FN5 is doped to form the channel 520, the source 540 and the drain 550 are formed and then a dielectric layer ILD5 is formed. The source 540 and the drain 550 are formed at the same side of the dummy gate DG5.

Next, in the S180, as shown in the drawing (h) of the FIG. 9, the dummy gate DG5 is replaced by the gate electrode 510. In this step, the gate dielectric layer 530 and a field plate FP5 are formed between the gate electrode 510 and the channel 520.

According to the disclosure in the FIGS. 4 and 9, the transistor 500 having the finger shaped channel 520 is formed. The channel 520 is long, so the resistance of the channel 520 is large. High resistance of the channel 520 could allow the transistor 500 to sustain high voltage operation without breakdown.

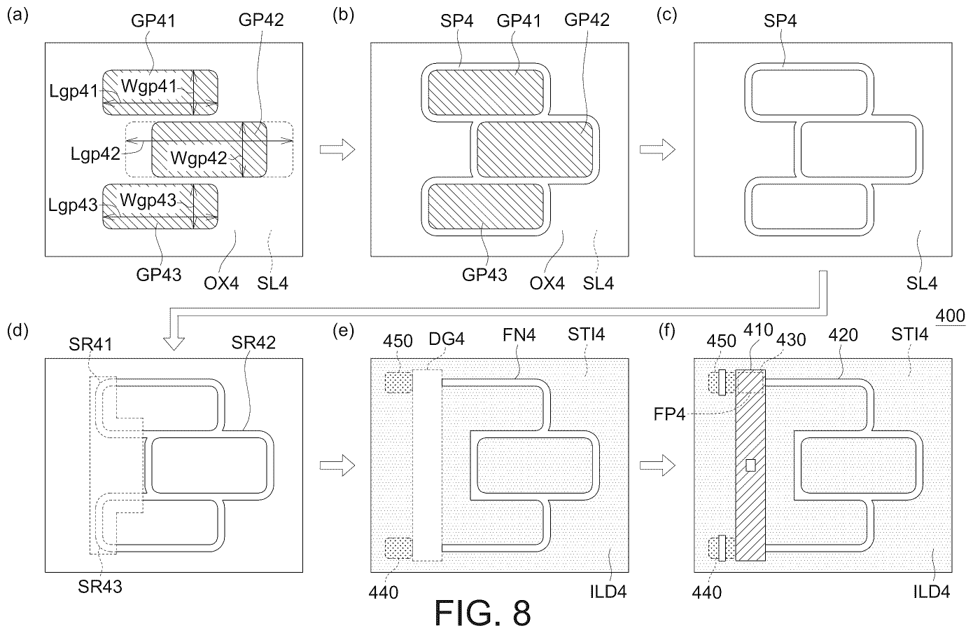

Please refer to FIG. 10, which shows a top view of a transistor 600 according to another embodiment of the present disclosure. The transistor 600 includes a first gate electrode 611, a second gate electrode 612, a third gate electrode 613, a channel 620, a first gate dielectric layer 631, a second gate dielectric layer 632, a third gate dielectric layer 633, a source 640 and a drain 650. The channel 620 is curved. For example, the channel 620 is U shaped. The first gate dielectric layer 631 is disposed between the first gate electrode 611 and the channel 620, the second gate dielectric layer 632 is disposed between the second gate electrode 612 and the channel 620, and the third gate dielectric layer 633 is disposed between the third gate electrode 613 and the channel 620. The source 640 is connected to the channel 620. The drain 650 is connected to the channel 620.

As shown in the FIG. 10, a length L611 of the first gate electrode 611, a length L612 of the second gate electrode 612 and a length L613 of the third gate electrode 613 are substantially equal.

The source 640 and the drain 650 are located at one side of the first gate electrode 611, the second gate electrode 612 is located at another side of the first gate electrode 611, and the second gate electrode 612 is located between the first gate electrode 611 and the third gate electrode 613.

The channel 620 has two corners C621, C622, and the third gate electrode 613 covers the two corners C621, C622. The first gate electrode 611 and the second gate electrode 612 do not cover the two corners C621, C622.

A distance D6112 between the first gate electrode 611 and the second gate electrode 612 is substantially equal to a distance D6123 between the second gate electrode 612 and the third gate electrode 613.

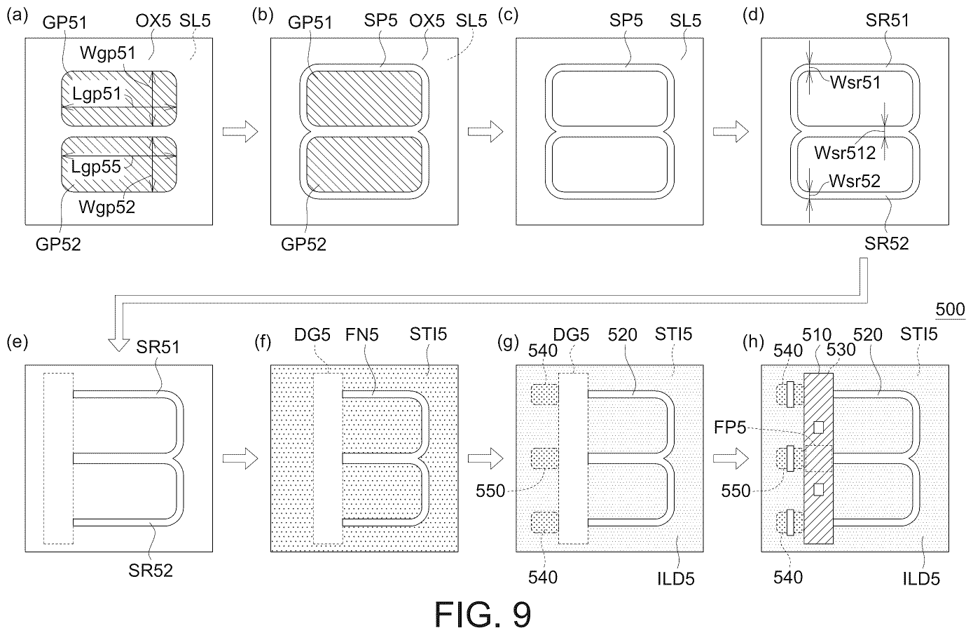

Please refer to FIG. 11A, which shows a cross-sectional view along a section line X-X′-3 in FIG. 10. At the section line X-X′-3, the gate electrodes 611, 612, 613 are disposed above a N⁻ well 628. An oxide layer 615 is disposed between the gate electrodes 611, 612, 613 and the N⁻ well 628. The spacers 614 cover the lateral walls of the gate electrodes 611, 612, 613 and the top surface 628a of the N⁻ well 628. The drain 650 is disposed in a silicon layer 690. The silicon layer 690 may be slightly doped P-type dopants. A contact 670 is disposed on the drain 650. An interlayer dielectric (ILD) layer 680 covers the drain 650 and the N⁻ well 628.

Please refer to FIG. 11B, which shows a cross-sectional view along a section line Y-Y′-3 in FIG. 10. At the section line Y-Y′-3, the gate electrode 611 is disposed above a STI structure 660 and coves a N⁻ fin 628f and a silicon fin 690f. The oxide layer 615 covers the N⁻ fin 628f. The high-k layer 612 and the interlayer 613 cover the silicon fin 690f.

Please refer to FIG. 11C, which shows a cross-sectional view along a section line Y-Y′-4 in FIG. 10. At the section line Y-Y′-4, the gate electrode 612 is disposed above the STI structure 660 and coves the N⁻ fin 628f and the silicon fin 690f. The oxide layer 615 covers the N⁻ fin 628f. The high-k layer 612 and the interlayer 613 cover the silicon fin 690f.

As shown in the FIG. 10, the transistor 600 has the U shaped channel 620. The channel 620 is long, so the resistance of the channel 620 is large. High resistance of the channel 620 could allow the transistor 600 to sustain high voltage operation without breakdown. According to the deign need, the second gate electrode 612 and the third gate electrode 613 could be used to adjust the resistance of the channel 620 to optimize the efficiency of the transistor 600.

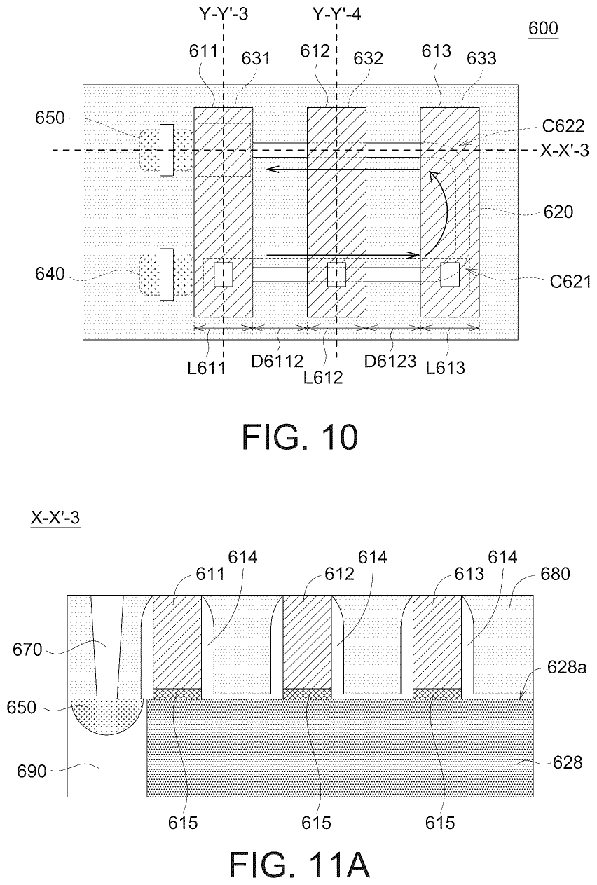

Please refer to FIG. 12, which shows a top view of a transistor 600′ according to another embodiment of the present disclosure. The transistor 600′ includes a first gate electrode 611′, a second gate electrode 612′, a third gate electrode 613′, a channel 620′, a first gate dielectric layer 631′, a second gate dielectric layer 632′, a third gate dielectric layer 633′, a source 640′ and a drain 650′. The channel 620′ is curved. For example, the channel 620′ is U shaped. The first gate dielectric layer 631′ is disposed between the first gate electrode 611′ and the channel 620′, the second gate dielectric layer 632′ is disposed between the second gate electrode 612′ and the channel 620′, and the third gate dielectric layer 633′ is disposed between the third gate electrode 613′ and the channel 620′. The source 640′ is connected to the channel 620′. The drain 650′ is connected to the channel 620′.

As shown in the FIG. 12, a length L611′ of the first gate electrode 611′, a length L612′ of the second gate electrode 612′ and a length L613′ of the third gate electrode 613′ are substantially equal.

The source 640′ is located at one side of the first gate electrode 611′, the drain 650′ is located at another side of the first gate electrode 611′, the source 640′ is located between the first gate electrode 611′ and the second gate electrode 612′, and the second gate electrode 612′ is located between the source 640′ and the third gate electrode 613′.

The channel 620′ has two corners C621′, C622′, and the third gate electrode 613′ covers the two corners C621′, C622′. The first gate electrode 611′ and the second gate electrode 612′ do not cover the two corners C621′, C622′.

A distance D6112′ between the first gate electrode 611′ and the second gate electrode 612′ is substantially equal to a distance D6123′ between the second gate electrode 612′ and the third gate electrode 613′.

As shown in the FIG. 12, the transistor 600′ has the U shaped channel 620′. The channel 620′ is long, so the resistance of the channel 620′ is large. High resistance of the channel 620′ could allow the transistor 600′ to sustain high voltage operation without breakdown. According to the deign need, the second gate electrode 612′ and the third gate electrode 613′ could be used to adjust the resistance of the channel 620′ to optimize the efficiency of the transistor 600′.

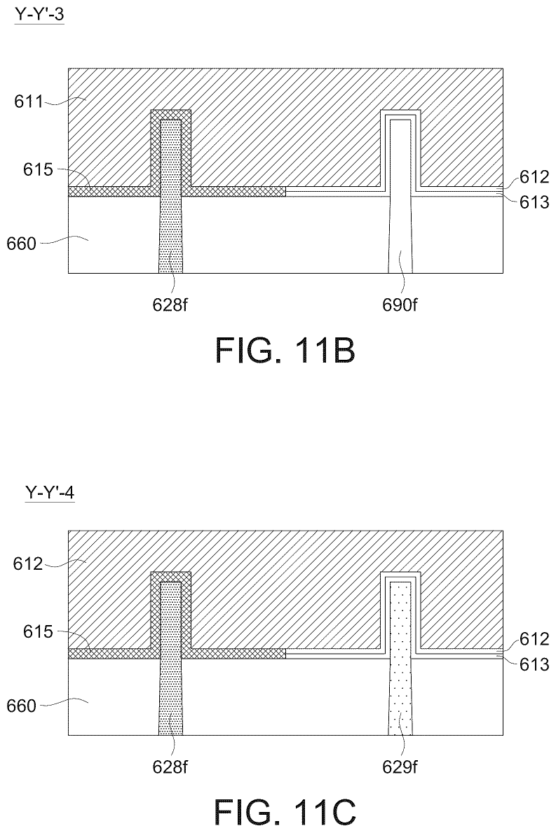

Please refer to FIG. 13, which shows a top view of a transistor 700 according to another embodiment of the present disclosure. The transistor 700 includes a first gate electrode 711, a channel 720, a first gate dielectric layer 731, a source 740 and a drain 750. The channel 720 is curved. For example, the channel 720 is U shaped. The first gate dielectric layer 731 is disposed between the first gate electrode 711 and the channel 720. The source 740 is connected to the channel 720. The drain 750 is connected to the channel 720.

As shown in the FIG. 13, a length L711 of the second gate electrode 711 is larger than a length L611′ (show in FIG. 12) of the first gate electrode 611. For example, the length L711 is 1 to 15 times more than the length L611′.

The source 740 and the drain 750 are located at one side of the first gate electrode 711.

As shown in the FIG. 13, the transistor 700 has the U shaped channel 720. The channel 720 is long, so the resistance of the channel 720 is large. High resistance of the channel 720 could allow the transistor 700 to sustain high voltage operation without breakdown. According to the deign need, the second gate electrode 712 could be used to adjust the resistance of the channel 720 to optimize the efficiency of the transistor 700.

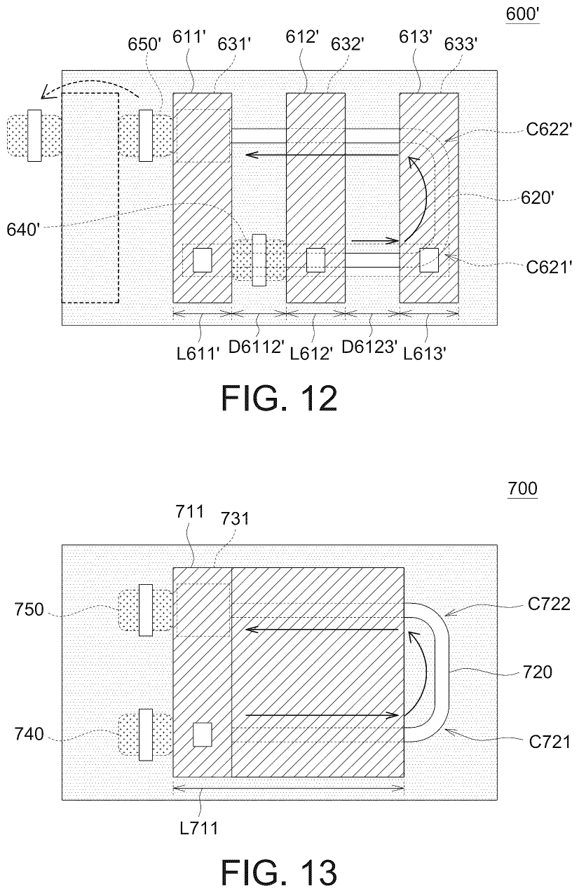

Please refer to FIG. 14, which shows a top view of a transistor 700′ according to another embodiment of the present disclosure. The transistor 700′ includes a first gate electrode 711′, a second gate electrode 712′, a channel 720′, a first gate dielectric layer 731′, a second gate dielectric layer 732′, a source 740′ and a drain 750′. The channel 720′ is curved. For example, the channel 720′ is U shaped. The first gate dielectric layer 731′ is disposed between the first gate electrode 711′ and the channel 720′, and the second gate dielectric layer 732′ is disposed between the second gate electrode 712′ and the channel 720′. The source 740′ is connected to the channel 720′. The drain 750′ is connected to the channel 720′.

As shown in the FIG. 14, a length L712′ of the second gate electrode 712′ is larger than a length L711′ of the first gate electrode 711′. For example, the length L712′ is 1 to 15 times more than the length L711′.

The source 740′ is located between the first gate electrode 711′ and the second gate electrode 712′. The drain 750′ is located at one side of the first gate electrode 711′.

The channel 720′ has two corners C721′, C722′, and the second gate electrode 712′ covers the two corners C721′, C722′. The first gate electrode 711′ does not cover the two corners C721′, C722′.

As shown in the FIG. 14, the transistor 700′ has the U shaped channel 720′. The channel 720′ is long, so the resistance of the channel 720′ is large. High resistance of the channel 720 could allow the transistor 700 to sustain high voltage operation without breakdown. According to the deign need, the second gate electrode 712′ could be used to adjust the resistance of the channel 720′ to optimize the efficiency of the transistor 700′.

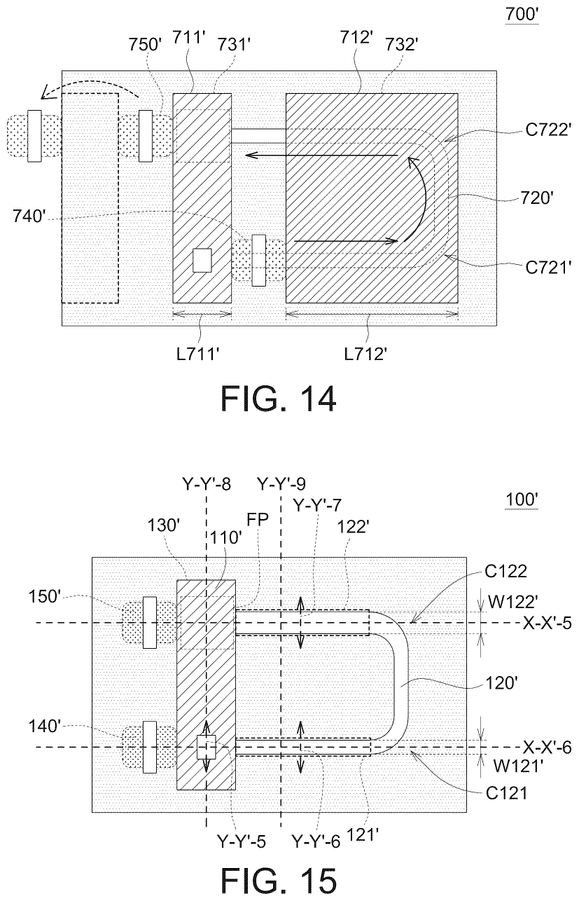

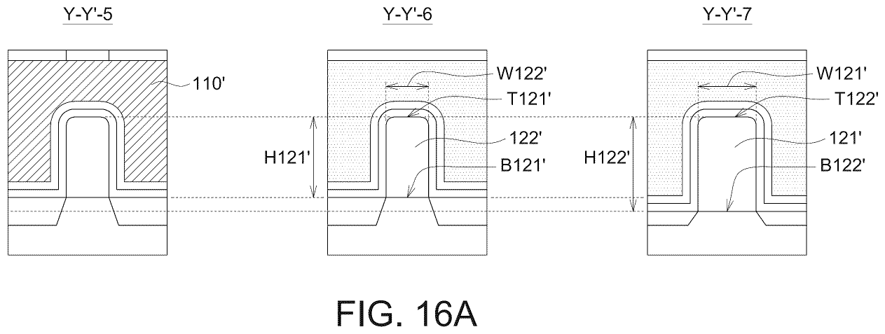

Please refer to FIGS. 15 and 16A. The FIG. 15 shows a top view of a transistor 100′ according to another embodiment of the present disclosure. The FIG. 16A shows cross-sectional views along section lines Y-Y′-5, Y-Y′-6, Y-Y′-7 in FIG. 15. The transistor 100′ includes a gate electrode 110′, a channel 120′, a gate dielectric layer 130′, a source 140′ and a drain 150′. The channel 120′ is curved. The gate dielectric layer 130′ is disposed between the gate electrode 110′ and the channel 120′. The source 140′ is connected to the channel 120′. The drain 150′ is connected to the channel 120′.

As shown in the FIG. 15, the channel 120′ is U shaped. The channel 120′ has two corners C121′, C122′. Most of the channel 120′ is not covered by the gate electrode 110′.

As shown in the FIG. 15, a width W121′ of a first portion 121′ of the channel 120′ is different from a width W122′ of a second portion 122′ of the channel 120′. For example, the width W122′ of the second portion 122′ of the channel 120′, which is close to the drain 150, is larger than the width W121′ of the first portion 121′ of the channel 120′, which is close to the source 140.

As shown in the FIG. 15, a doping concentration of a first portion 121′ of the channel 120′ is different from a doping concentration of a second portion 122′ of the channel 120′. For example, the doping concentration of the second portion 122′ of the channel 120′, which is close to the drain 150, is less than the doping concentration of the first portion 121′ of the channel 120′, which is close to the source 140.

As shown in the FIG. 16A, a first height H121′ (from the fin top T121′ to the fin bottom B121′) of the first portion 121′ of the channel 120′ is different from a second height H122′ (from the fin top T122′ to the fin bottom B122′) of the second portion 122′ of the channel 120′. For example, the second height H122′ (from the fin top T122′ to the fin bottom B122′) of the second portion 122′ of the channel 120′, which is close to the drain 150, is larger than the first height H121′ (from the fin top T121′ to the fin bottom B121′) of the first portion 121′ of the channel 120′, which is close to the source 140.

Please refer to FIG. 16B, which shows a cross-sectional view along a section line X-X′-5 in FIG. 15. At the section line X-X′-5, the gate electrode 110′ is disposed above a N⁻ well 128′. An oxide layer 115′ is disposed between the gate electrode 110′ and the N⁻ well 128′. A spacer 114′ covers the lateral walls of the gate electrode 110′ and the top surface 128a′ of the N⁻ well 128′. The drain 150′ is disposed in a silicon layer 190′. The silicon layer 190′ may be slightly doped P-type dopants. A contact 170′ is disposed on the drain 150′. An interlayer dielectric (ILD) layer 180′ covers the drain 150′ and the N⁻ well 128′.

Please refer to FIG. 16C, which shows a cross-sectional view along a section line X-X′-6 in FIG. 15. At the section line X-X′-6, the gate electrode 110′ is disposed above the silicon layer 190′. A high-k layer 112′ and an interlayer 113′ are disposed between the gate electrode 110′ and the silicon layer 190′. The spacer 114′ covers the lateral walls of the gate electrode 110′, a top surface 129a′ of the N⁺ well 129′ and the top surface 128a′ of the N⁻ well 128′. The doping concentration is gradually decreased from the N⁺ well 129′ to the N⁻ well 128′. The source 140′ is disposed in the silicon layer 190′. The contact 170′ is disposed on the source 140′. The ILD layer 180′ covers the source 140′, the N⁺ well 129′ and the N⁻ well 128′.

Please refer to FIG. 16D, which shows a cross-sectional view along a section line Y-Y′-8 in FIG. 15. At the section line Y-Y′-8, the gate electrode 110′ is disposed above a STI structure 160′ and coves a N⁻ fin 128f′ and a silicon fin 190f′. The oxide layer 115′ covers the N⁻ fin 128f′. The high-k layer 112′ and the interlayer 113′ cover the silicon fin 190f′.

Please refer to FIG. 16E, which shows a cross-sectional view along a section line Y-Y′-9 in FIG. 15. At the section line Y-Y′-9, the IDL 180′ is disposed above the STI structure 160′ and coves the N⁻ fin 128f′ and a N⁺ fin 129f′. The oxide layer 115′ covers the N⁻ fin 128f′ and the N⁺ fin 129f′.

As shown in the FIGS. 15 to 16E, the transistor 100′ has the U shaped channel 120′. The channel 120′ is long, so the resistance of the channel 120′ is large. High resistance of the channel 120′ could allow the transistor 100′ to sustain high voltage operation without breakdown. According to the deign need, the size of the channel 120′ and the doping concentration of the channel 120′ could be varied at different locations. As such, the resistance of the channel 120′ could be adjusted to optimize the efficiency of the transistor 100′.

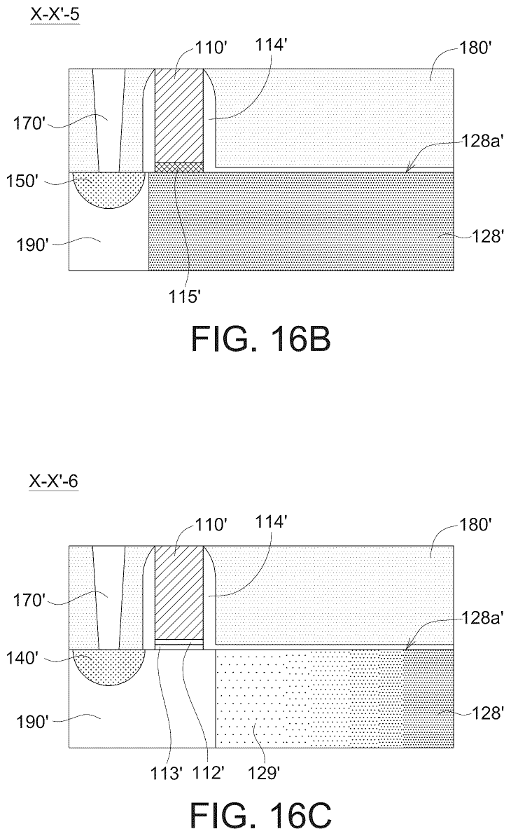

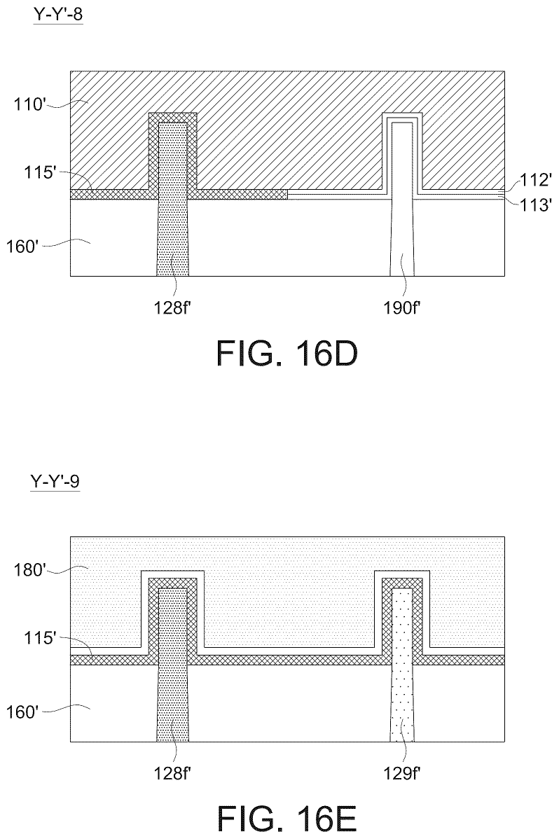

Please refer to FIGS. 17 and 18. The FIG. 17 shows a top view of a transistor 800 and a transistor 800′ according to another embodiment of the present disclosure. The FIG. 18 shows a circuit diagram of the transistor 800 and the transistor 800′ in the FIG. 17. The transistor 800 includes a gate electrode 810, a channel 820, a gate dielectric layer 830, a source 840 and a drain 850. The channel 820 is curved. The gate dielectric layer 830 is disposed between the gate electrode 810 and the channel 820. The source 840 is connected to the channel 820. The drain 850 is connected to the channel 820. The transistor 800′ includes a gate electrode 810′, a channel 820′, a gate dielectric layer 830′, a source 840′ and the drain 850. The channel 820′ is curved. The gate dielectric layer 830′ is disposed between the gate electrode 810′ and the channel 820′. The source 840′ is connected to the channel 820′. The drain 850 is connected to the channel 820′.

As shown in the FIGS. 17 and 18, the source 840, the drain 850 and the source 840′ are located between the gate electrode 810 and the gate electrode 810′. The transistor 800 and the transistor 800′ share the same drain 850. The channel 820 and the channel 820′ form an S shaped strip. The shared drain 850 is located at the center of the S shaped strip.

As shown in the FIGS. 17 and 18, the transistor 800 and transistor 800′ have the U shaped channel 820 and the U shaped channel 820′. The channels 820 and the channel 820′ are long, so the resistance of each of the channels 820, 820′ is large. High resistance of the channels 820, 820′ could allow the transistor 800, 800′ to sustain high voltage operation without breakdown.

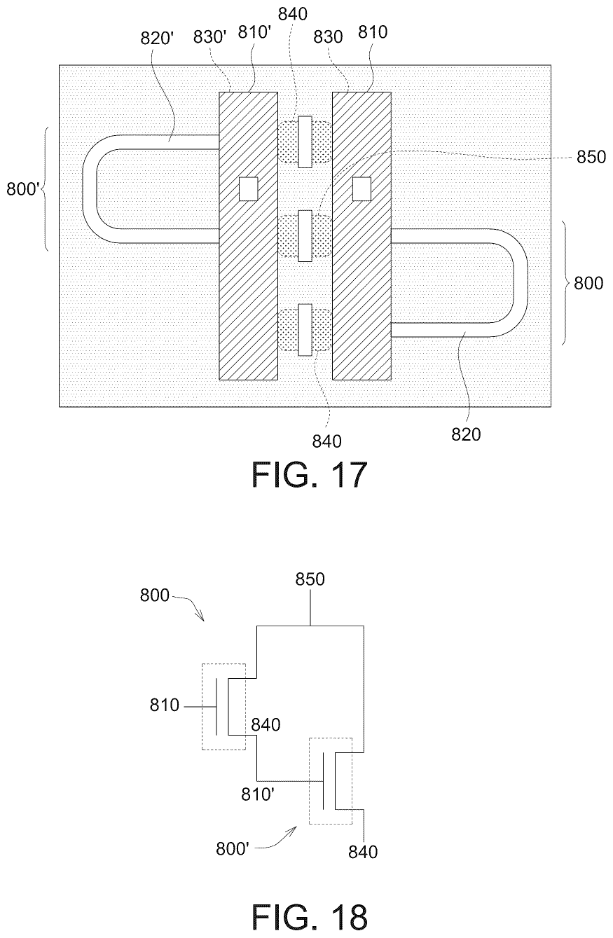

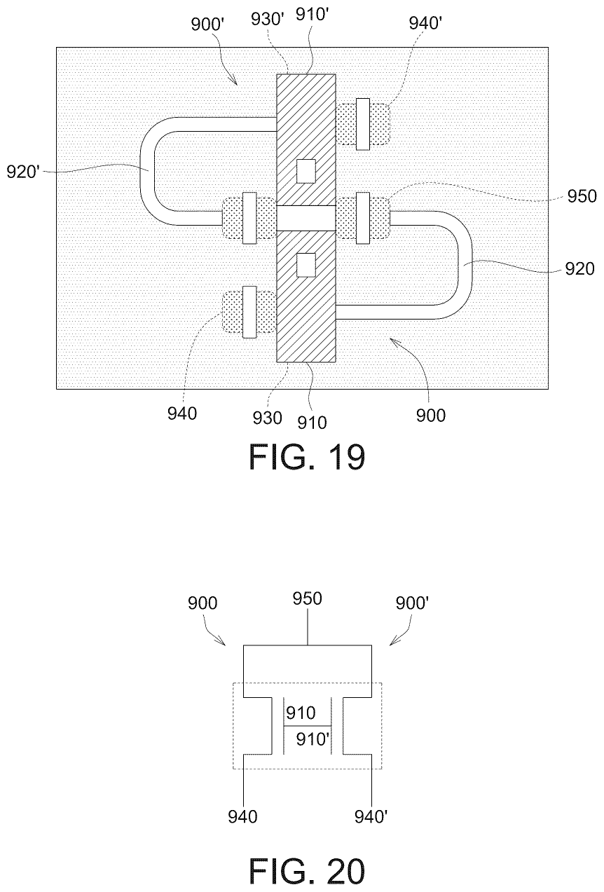

Please refer to FIGS. 19 and 20. The FIG. 19 shows a top view of a transistor 900 and a transistor 900′ according to another embodiment of the present disclosure. FIG. 20 shows a circuit diagram of the transistor 900 and the transistor 900′ in the FIG. 19. The transistor 900 includes a gate electrode 910, a channel 920, a gate dielectric layer 930, a source 940 and a drain 950. The channel 920 is curved. The gate dielectric layer 930 is disposed between the gate electrode 910 and the channel 920. The source 940 is connected to the channel 920. The drain 950 is connected to the channel 920. The transistor 900′ includes a gate electrode 910′, a channel 920′, a gate dielectric layer 930′, a source 940′ and the drain 950. The channel 920′ is curved. The gate dielectric layer 930′ is disposed between the gate electrode 910′ and the channel 920′. The source 940′ is connected to the channel 920′. The drain 950 is connected to the channel 920′.

As shown in the FIGS. 19 and 20, the gate electrode 910 and the gate electrode 910′ are electrically connected with each other. The source 940 and the source 940′ are located at two opposite sides of the gate electrode 910 and the gate electrode 910′. The drain 950 is disposed at two sides of the gate electrode 910 and the gate electrode 910′. The transistor 900 and the transistor 900′ share the same drain 950. The channel 920 and the channel 920′ form an S shaped strip. The shared drain 950 is located at the center of the S shaped strip.

As shown in the FIGS. 19 and 20, the transistor 900 and transistor 900′ have the U shaped channel 920 and the U shaped channel 920′. The channels 920 and the channel 920′ are long, so the resistance of each of the channels 920, 920′ is large. High resistance of the channel 920, 920′ could allow the transistor 900, 900′ to sustain high voltage operation without breakdown.

According to one embodiment, a transistor is provided. The transistor includes at least one gate electrode, a channel, a gate dielectric layer, a source and a drain. The channel is curved. A doping concentration of a first portion of the channel is different from a doping concentration of a second portion of the channel. The gate dielectric layer is disposed between the gate electrode and the channel. The source is connected to the channel. The drain is connected to the channel.

Based on the transistor described in the previous embodiments, the channel is covered on more than one lattice plane.

Based on the transistor described in the previous embodiments, a width of a first portion of the channel is different from a width of a second portion of the channel.

Based on the transistor described in the previous embodiments, the first portion is close to the source, the second portion is close to the drain, and the width of the second portion of the channel is larger than the width of the first portion of the channel.

Based on the transistor described in the previous embodiments, a first height of a first portion of the channel is different from a second height of a second portion of the channel.

Based on the transistor described in the previous embodiments, the first portion is close to the source, the second portion is close to the drain, and the second height of the second portion of the channel is larger than the first height of the first portion of the channel.

Based on the transistor described in the previous embodiments, the first portion is close to the source, the second portion is close to the drain, and a first bottom of the first portion of the channel is higher than a second bottom of the second portion of the channel.

Based on the transistor described in the previous embodiments, the first portion is close to the source, the second portion is close to the drain, and the doping concentration of the second portion of the channel is less than the doping concentration of the first portion of the channel.

Based on the transistor described in the previous embodiments, the channel is U shaped, Ω shaped, M shaped, ring shaped, or finger shaped.

According to another embodiment, a transistor is provided. The transistor includes at least two gate electrodes, a channel, at least two gate dielectric layers, a source and a drain. The channel is curved. The channel has two corners. One of the gate electrodes covers the two corners. The at least two gate dielectric layers are respectively disposed between the gate electrodes and the channel. The source is connected to the channel. The drain is connected to the channel.

Based on the transistor described in the previous embodiments, the at least two gate electrodes include a first gate electrode, a second gate electrode and a third gate electrode, a length of the first gate electrode, a length of the second gate electrode and a length of the third gate electrode are substantially equal.

Based on the transistor described in the previous embodiments, the source and the drain are located at one side of the first gate electrode, the second gate electrode is located at another side of the first gate electrode, and the second gate electrode is located between the first gate electrode and the third gate electrode.

Based on the transistor described in the previous embodiments, the source is located at one side of the first gate electrode, the drain is located at another side of the first gate electrode, the source is located between the first gate electrode and the second gate electrode, and the second gate electrode is located between the source and the third gate electrode.

Based on the transistor described in the previous embodiments, a distance between the first gate electrode and the second gate electrode is substantially equal to a distance between the second gate electrode and the third gate electrode.

Based on the transistor described in the previous embodiments, at least two gate electrodes include a first gate electrode and a second gate electrode, and the source is located between the first gate electrode and the second gate electrode.

Based on the transistor described in the previous embodiments, the channel has two corners, and the second gate electrode covers the two corners.

Based on the transistor described in the previous embodiments, in the step of cutting part of the silicon ring, two corners of the silicon ring are cut.

Based on the transistor described in the previous embodiments, in the step of forming the source and the drain, the source and the drain are formed at the side opposite to the channel.

Based on the transistor described in the previous embodiments, in the step of transferring the pattern of the spacer to the silicon layer to form the at least one silicon ring, a quantity of the at least one silicon ring is three, and the three silicon rings are overlapped.

According to another embodiment, a manufacturing method of a transistor is provided. The manufacturing method of the transistor includes: forming a ground pattern on a silicon layer; forming a spacer around the ground pattern; removing the ground pattern; transferring a pattern of the spacer to the silicon layer to form a silicon ring; cutting part of the silicon ring; forming a shallow trench isolation, recessing the shallow trench isolation to form a fin and forming a dummy gate; doping the fin, forming a source and a drain and forming a dielectric layer; and replacing the dummy gate by a gate electrode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A transistor, comprising:
at least one gate electrode;
a channel, wherein the channel is curved, and a doping concentration of a first portion of the channel is different from a doping concentration of a second portion of the channel;
a gate dielectric layer, disposed between the gate electrode and the channel;
a source, connected to the channel; and
a drain, connected to the channel.

2. The transistor according to claim 1, wherein the channel is covered on more than one lattice plane.

3. The transistor according to claim 1, wherein a width of a first portion of the channel is different from a width of a second portion of the channel.

4. The transistor according to claim 3, wherein the first portion is close to the source, the second portion is close to the drain, and the width of the second portion of the channel is larger than the width of the first portion of the channel.

5. The transistor according to claim 1, wherein a first height of a first portion of the channel is different from a second height of a second portion of the channel.

6. The transistor according to claim 5, wherein the first portion is close to the source, the second portion is close to the drain, and the second height of the second portion of the channel is larger than the first height of the first portion of the channel.

7. The transistor according to claim 5, wherein the first portion is close to the source, the second portion is close to the drain, and a first bottom of the first portion of the channel is higher than a second bottom of the second portion of the channel.

8. The transistor according to claim 1, wherein the first portion is close to the source, the second portion is close to the drain, and the doping concentration of the second portion of the channel is less than the doping concentration of the first portion of the channel.

9. The transistor according to claim 1, wherein the channel is U shaped, Q shaped, M shaped, ring shaped, or finger shaped.

10. A transistor, comprising:
at least two gate electrodes;
a channel, wherein the channel is curved, the channel has two corners, and one of the gate electrodes covers the two corners;
at least two gate dielectric layers, respectively disposed between the gate electrodes and the channel;
a source, connected to the channel; and
a drain, connected to the channel.

11. The transistor according to claim 10, wherein the at least two gate electrodes include a first gate electrode, a second gate electrode and a third gate electrode, a length of the first gate electrode, a length of the second gate electrode and a length of the third gate electrode are substantially equal.

12. The transistor according to claim 11, wherein the source and the drain are located at one side of the first gate electrode, the second gate electrode is located at another side of the first gate electrode, and the second gate electrode is located between the first gate electrode and the third gate electrode.

13. The transistor according to claim 11, wherein the source is located at one side of the first gate electrode, the drain is located at another side of the first gate electrode, the source is located between the first gate electrode and the second gate electrode, and the second gate electrode is located between the source and the third gate electrode.

14. The transistor according to claim 11, wherein a distance between the first gate electrode and the second gate electrode is substantially equal to a distance between the second gate electrode and the third gate electrode.

15. The transistor according to claim 10, wherein at least two gate electrodes include a first gate electrode and a second gate electrode, and the source is located between the first gate electrode and the second gate electrode.

16. The transistor according to claim 15, wherein the channel has two corners, and the second gate electrode covers the two corners.

17. A manufacturing method of a transistor, comprising:
forming a ground pattern on a silicon layer;
forming a spacer around the ground pattern;
removing the ground pattern;
transferring a pattern of the spacer to the silicon layer to form at least one silicon ring;
cutting part of the silicon ring;
forming a shallow trench isolation, recessing the shallow trench isolation to form a fin and forming a dummy gate;
doping the fin, forming a source and a drain and forming a dielectric layer; and
replacing the dummy gate by a gate electrode.

18. The manufacturing method according to claim 17, wherein in the step of cutting part of the silicon ring, two corners of the silicon ring are cut.

19. The manufacturing method according to claim 17, wherein in the step of forming the source and the drain, the source and the drain are formed at the side opposite to the channel.

20. The manufacturing method according to claim 17, wherein in the step of transferring the pattern of the spacer to the silicon layer to form the at least one silicon ring, a quantity of the at least one silicon ring is three, and the three silicon rings are overlapped.
